(19) United States
(12) Patent Application Publication
(10) Pub. No.: US 2026/0052811 A1
(43) Pub. Date: Feb. 19, 2026

(54) RADIATION-EMITTING SEMICONDUCTOR COMPONENT AND METHOD FOR PRODUCING RADIATION-EMITTING SEMICONDUCTOR COMPONENTS

(71) Applicant: ams-OSRAM International GmbH, Regensburg (DE)

(72) Inventor: Thomas Schwarz, Regensburg (DE)

(21) Appl. No.: 18/996,207

(22) PCT Filed: Aug. 22, 2023
(86) PCT No.: PCT/EP2023/072975

§ 371 Date: Jan. 17, 2025

(30) Foreign Application Priority Data
Aug. 25, 2022 (DE) 10 2022 121 519.9

(51) Int. Cl. H10H 20/853; H10H 20/01; H10H 20/85; H10H 20/851; H10H 20/854; H10H 20/856; H10H 20/857

(52) U.S. Cl. CPC H10H 20/853; H10H 20/0361; H10H 20/0362; H10H 20/8506; H10H 20/8508; H10H 20/8512; H10H 20/854; H10H 20/856; H10H 20/857

(57) ABSTRACT

In an embodiment a radiation-emitting semiconductor component includes a carrier having a first main surface and at least one lateral surface extending transversely to the first main surface, at least one semiconductor chip arranged on the first main surface of the carrier and configured to emit radiation at a radiation emission face and a housing molded onto the carrier and the at least one semiconductor chip, wherein the at least one lateral surface of the carrier is uncovered by the housing, wherein the housing comprises a depression arranged on the radiation emission face of the at least one semiconductor chip, wherein the housing is laterally delimited by at least one housing wall, and wherein the at least one housing wall is laterally offset in a direction toward the depression with respect to an edge of the carrier delimiting the first main surface.

### CROSS-REFERENCE TO RELATED APPLICATIONS

This patent application is a national phase filing under section 371 of PCT/EP2023/072975, filed Aug. 22, 2023, which claims the priority of German patent application no. 102022121519.9, filed Aug. 25, 2022, each of which is incorporated herein by reference in its entirety.

### TECHNICAL FIELD

A radiation-emitting semiconductor component and a method for producing radiation-emitting semiconductor components are specified. The radiation-emitting semiconductor component can be intended for the emission of white light and can be produced with small component size or luminescent area.

### BACKGROUND

Various designs of white light-emitting diodes of small component size, i.e., for example, smaller than 2.5 mm×2.5 mm, are known. For example, the light-emitting diode can comprise a so-called QFN (quad flat no-lead) housing having a dam dosed on, which can be formed using silicone, wherein a converter material is arranged inside the dam. During production in the composite, however, silicone can reach separating trenches, which are intended for the isolation of light-emitting diodes from the composite, so that a multistage separating process is necessary, since silicone is soft and smears on a saw blade. Furthermore, flipchips having a sprayed-on converter layer and two electric contacts on the rear side are known, wherein the electric contacts are embedded in an epoxy molding compound. The heat dissipation is impaired due to the epoxy molding compound. In addition, these flipchips are relatively sensitive to fracture.

### SUMMARY

Embodiments provide, inter alia, a stable radiation-emitting semiconductor component. Further embodiments provide, inter alia, an efficient method for producing stable radiation-emitting semiconductor components.

According to at least one embodiment of a radiation-emitting semiconductor component, it comprises a carrier having a first main surface and at least one lateral surface extending transversely, for example, perpendicularly, to the first main surface. The number of the lateral surfaces depends on the three-dimensional design of the carrier. For example, the carrier can have a cuboid design and therefore can comprise four lateral surfaces extending transversely or perpendicularly to the first main surface. For example, the carrier can comprise a lead frame, a printed circuit board, or a ceramic substrate.

According to at least one embodiment, the radiation-emitting semiconductor component comprises at least one semiconductor chip arranged on the first main surface of the carrier. The at least one semiconductor chip can emit radiation at a radiation emission face in operation. The radiation emission face can be located on a side of the at least one semiconductor chip opposite to the carrier or facing away from the carrier and can delimit the semiconductor chip on this side. The at least one semiconductor chip can have at least one lateral surface extending transversely, for example, perpendicularly, to the radiation emission face. The number of the lateral surfaces depends on the three-dimensional design of the semiconductor chip. For example, the at least one semiconductor chip can comprise a cuboid design and therefore can comprise four lateral surfaces extending transversely or perpendicularly to the first main surface.

The at least one semiconductor chip can be a surface emitter, a volume emitter, or a flipchip. A surface-emitting semiconductor chip can comprise an electrical contact on its upper side and an electrical contact on its lower side. A volume-emitting semiconductor chip can comprise both electrical contacts on its upper side. A flipchip can comprise both electrical contacts on its lower side.

According to at least one embodiment, the radiation-emitting semiconductor component comprises a housing. The housing can be molded onto the carrier and the at least one semiconductor chip. In other words, the housing can be mechanically connected to the carrier and the at least one semiconductor chip without additional connecting means such as adhesive and can cling to the carrier or the at least one semiconductor chip in areas in which it is molded on.

According to at least one embodiment or design, the at least one lateral surface of the carrier is uncovered by the housing. In particular, all lateral surfaces of the carrier are uncovered by the housing. In addition, a second main surface of the carrier opposite to the first main surface can also be uncovered by the housing. The uncovered surfaces of the carrier enable good heat dissipation.

Furthermore, the at least one semiconductor chip can be covered by the housing on the at least one lateral surface or on all lateral surfaces. The housing can extend from the first main surface of the carrier over the lateral surface(s) of the at least one semiconductor chip to beyond the radiation emission face of the semiconductor chip.

According to at least one embodiment or design, the housing comprises a depression which is arranged on the radiation emission face of the semiconductor chip. The depression can be arranged on a side of the semiconductor chip facing away from the carrier.

According to at least one embodiment or design, the housing is laterally delimited by at least one housing wall. The number of the housing walls which laterally delimit the housing depends on the three-dimensional design of the housing. For example, the housing can comprise a cuboid design and therefore can comprise four housing walls.

According to at least one embodiment or design, the at least one housing wall is or all housing walls are at least in some sections offset laterally in the direction toward the depression in relation to an edge of the carrier delimiting the first main surface. In other words, the at least one housing wall or all housing walls can comprise at least in some areas a lateral distance to the edge of the carrier in a perpendicular projection on the first main surface of the carrier. The lateral distance can be defined parallel to the first main surface. The lateral distance to the edge is greater than zero in this case and can be at most 20 μm, for example. For example, the at least one housing wall or all housing walls can be set back at least in some areas from the edge of the carrier.

The lateral distance results from separating trenches, which are provided during the production in the composite between adjacent housings, as will be explained in more detail hereinafter in conjunction with the method.

According to at least one embodiment of a radiation-emitting semiconductor component, it comprises:
a carrier having a first main surface and at least one lateral surface extending transversely to the first main surface,
at least one semiconductor chip, which is arranged on the first main surface of the carrier and emits radiation at a radiation emission face in operation,
a housing, which
is molded onto the carrier and the at least one semiconductor chip, wherein the at least one lateral surface of the carrier is uncovered by the housing,
comprises a depression, which is arranged on the radiation emission face of the at least one semiconductor chip, and
is laterally delimited by at least one housing wall,
wherein the at least one housing wall is laterally offset at least in some sections in the direction toward the depression in relation to an edge of the carrier delimiting the first main surface.

The radiation-emitting semiconductor component can advantageously be formed small having a component size of at most 2 mm x at most 2 mm.

The at least one semiconductor chip can comprise a first and second semiconductor area of different conductivities and an active zone, which is arranged between the first and second semiconductor areas and is intended for generating radiation. The first and second semiconductor area and the active zone can each be formed from one or more semiconductor layers. The semiconductor layers can be layers deposited epitaxially on a growth substrate. The growth substrate can remain in the semiconductor chip after the growth of the semiconductor layers or can be at least partially detached.

A quantum well structure, in particular a single quantum well structure (SQW) or multiple quantum well structure (MQW), can be formed in the active zone via the semiconductor layers.

Materials based on arsenide, phosphide, or nitride compound semiconductors come into consideration, for example, for the semiconductor areas or semiconductor layers. In the present context, “based on arsenide, phosphide, or nitride compound semiconductors” means that the semiconductor layers contain AlₙGaₘIn₁₋ₙ₋ₘAs, AlₙGaₘIn₁₋ₙ₋ₘP, or AlₙGaₘIn₁₋ₙ₋ₘN, wherein 0≤n≤1, 0≤m≤1, and n+m≤1 apply. This material does not necessarily have to comprise a mathematically exact composition according to the above formula here. Rather, it can comprise one or more dopants and additional components which essentially do not change the characteristic physical properties of the AlₙGaₘIn₁₋ₙ₋ₘAs, AlₙGaₘIn₁₋ₙ₋ₘP, or AlₙGaₘIn₁₋ₙ₋ₘN material. For the sake of simplicity, however, the above formula only includes the essential components of the crystal lattice (Al, Ga, In, As or P or N), even if they can be partially replaced by small quantities of further materials.

According to at least one embodiment or design, the housing is a housing molded using vacuum injection molding. In other words, the housing can be molded using VIM (vacuum injection molding), as will be explained in more detail hereinafter in conjunction with the method. The housing created using vacuum injection molding can comprise sharp edges having relatively small radius of curvature, for example, less than 10 μm.

According to at least one embodiment or design, the housing consists of a housing material containing a reflective material. For example, the housing can be formed as a reflector. The housing can be intended to reflect radiation emitted at the at least one lateral surface of the semiconductor chip with a reflectivity of at least 50%. A part of the radiation can be deflected in the direction of the depression. For example, the at least one semiconductor chip can emit electromagnetic radiation having a wavelength in the ultraviolet, visible, or infrared spectral range in operation.

The reflective material can comprise, for example, particles made of TiO2 and/or ZrO2. An average particle size is advantageously at most 1 μm here, wherein the average particle size is to be understood as the median value. Particles of this size can be processed well using vacuum injection molding.

Furthermore, the housing material can contain a plastic material. Silicone comes into consideration as a plastic material, for example. The reflective material or the particles can be homogeneously distributed in the plastic material.

According to at least one embodiment or design, a filler compound is arranged in the depression. The filler compound can completely fill the depression and preferably does not protrude beyond a housing upper side, which is arranged on a side of the housing facing away from the carrier. For example, the filler compound contains a converter material intended for wavelength conversion of the radiation. At least a part of the radiation emitted by the semiconductor chip can thus experience a change of the wavelength, for example, a shift toward longer wavelengths, due to the filler compound. By way of a superposition of a primary radiation coming from the semiconductor chip with a secondary radiation coming from the filler compound, it is possible that the radiation-emitting semiconductor component emits white light, for example, due to a combination of blue primary radiation and yellow secondary radiation, or colored light or even invisible radiation.

According to at least one embodiment or design, the depression extends from the housing upper side to the radiation emission face of the at least one semiconductor chip and ends at the radiation emission face. In other words, the depression does not protrude beyond the radiation emission face of the semiconductor chip in the direction of the carrier.

Furthermore, it is possible that the depression does not laterally protrude beyond the at least one semiconductor chip on a side facing toward it. In other words, the depression can have lateral dimensions on a side facing toward the at least one semiconductor chip, which are at most as large as the lateral dimensions of the radiation emission face, wherein the lateral dimensions can be defined parallel to the first main surface of the carrier.

According to at least one embodiment or design, the carrier comprises an opening into which the housing extends. The opening can thus be filled with housing material. It is possible that the carrier comprises multiple openings into which the housing extends.

For example, the opening extends from the first main surface of the carrier through the carrier to the second main surface of the carrier. The opening can be used during the production of the housing as a filling opening for a molding compound of the housing to be produced. It has proven to be advantageous for this purpose if the opening is smaller on the second main surface than on the first main surface. However, it is also possible that the opening is larger on the second main surface than on the first main surface. In this design, the housing can be anchored particularly well in the carrier by the housing material arranged in the opening.

The opening can comprise a trapezoidal or multistep cross section parallel to a plane extending perpendicular to the first main surface or second main surface. Furthermore, the opening can comprise a circular, elliptical, or polygonal cross section parallel to a plane extending parallel to the first main surface or second main surface.

According to at least one embodiment or design, the carrier comprises a first connection element of a first polarity and a second connection element of a second polarity different from the first polarity, wherein the second connection element is spaced apart from the first connection element by an electrically insulating intermediate space, for example. The opening can be arranged in the intermediate space. The opening can thus be arranged in a space-saving manner in an intermediate space provided in any case between the first and second connection element.

The method described hereinafter is suitable for the production of radiation-emitting semiconductor components of the above-mentioned type. Features described in conjunction with the radiation-emitting semiconductor component can therefore also be used for the method and vice versa.

According to at least one embodiment of a method for producing radiation-emitting semiconductor components, it comprises the following steps:
providing a carrier composite,
applying radiation-emitting semiconductor chips to the carrier composite, wherein the radiation-emitting semiconductor chips each comprise a radiation emission face,
providing a molding tool having cavities,
arranging the carrier composite having the radiation-emitting semiconductor chips applied thereon relative to the molding tool such that at least one radiation-emitting semiconductor chip is arranged in each cavity,
filling the cavities with a molding compound to produce housings, wherein the radiation-emitting semiconductor chips are each covered by a part of the molding tool to produce depressions in the housings at the radiation emission faces, and wherein each two adjacent cavities are spaced apart from one another by a further part of the molding tool to produce a separating trench between each two adjacent housings,
dividing the carrier composite having the radiation-emitting semiconductor chips applied thereon and the molded-on housings through the respective separating trench, wherein carriers of the radiation-emitting semiconductor components are isolated from the carrier composite, which each comprise a first main surface, on which at least one radiation-emitting semiconductor chip is arranged, and wherein the separating trenches are each formed wide enough that a housing wall of a housing adjoining thereon is offset at least in some sections laterally in the direction toward the depression after the isolation in relation to an edge of the carrier delimiting the first main surface, on which the housing is molded.

For example, the method steps can be carried out in the sequence indicated.

The relevant separating trench can have a width which corresponds to twice the lateral distance of the housing wall to the edge of the carrier. For example, the width of the separating trench can decrease with increasing depth. In other words, the separating trench can taper in the direction of the carrier composite. Accordingly, the housing wall in the finished semiconductor component can extend obliquely, i.e. neither perpendicular nor parallel, to the first main surface of the carrier. Furthermore, the separating trench can comprise a depth which corresponds to at least 50% of a height of the housing wall. The height can correspond to a vertical extension which is defined, for example, along a vertical direction extending transversely, in particular perpendicularly to the first main surface of the carrier.

The width or depth of the separating trench is in particular selected so that during the isolation, no or only little housing material, from each of which the housings are formed, has to be cut through. In particular, the separating trench is free of silicone. The isolation can therefore be carried out without preceding steps for eliminating the silicone in a one-step process, for example via sawing. In particular, the molding compound comprises the same material components as the housing material, which were already described above.

According to at least one embodiment or design, the housings are produced using vacuum injection molding (VIM). In this case, the molding compound can be injected into the cavities in which a vacuum is generated. A filling pressure prevailing during the injection can be between 0.1 and 0.5 bar. It is possible to implement small housing sizes with high precision using vacuum injection molding, so that correspondingly small component sizes can be implemented. A further advantage is that the formation of air bubbles, which generally make the housings fragile, can be prevented, so that the housings and accordingly also the radiation-emitting semiconductor components are comparatively stable.

According to at least one embodiment or design, parts of the molding tool which delimit the cavities are produced using additive manufacturing. It is possible via additive manufacturing to implement cavities having more complex geometry and accordingly also housings having more complex geometry. For example, the parts of the molding tool which delimit the cavities can contain or consist of polydimethylsiloxane (PDMS). Surfaces of the parts formed by PDMS are distinguished by a high surface quality.

According to at least one embodiment or design, a filler compound is introduced into the depressions via a dispenser. As already mentioned above, the filler compound can contain a converter material. The filler compound can additionally comprise the above-described structural properties and material properties.

According to at least one embodiment or design, the carrier composite comprises openings, wherein at least one opening is assigned to each carrier to be isolated. The molding compound can be introduced into the cavities through the openings. The openings, as already explained in more detail above, can therefore be used as filling openings and can comprise the structural features described above. During the filling of the cavities, the openings can be filled with molding compound at the same time, so that the housings each protrude into the associated openings and can therefore be anchored in the carriers.

According to at least one embodiment or design, providing the carrier composite comprises a step of providing a carrier body which comprises recesses. For example, the carrier body can be a lead frame composite, a composite made up of printed circuit boards, or a composite made up of ceramic substrates. A part of the recesses can be intended for the purpose of forming intermediate spaces between connection elements of different polarity in the isolated carriers. A further part of the recesses can be intended for the purpose of separating the connection elements of adjacent carriers to be isolated from one another by intermediate spaces.

Furthermore, providing the carrier composite can comprise a step of introducing a base material into the recesses. For example, the base material is introduced into the recesses using vacuum injection molding (VIM). The base material can differ from the molding compound from which the housings are produced. The base material can be a plastic material, for example, an epoxy. The epoxy is hard in comparison to silicone, so that the isolation of the carriers can take place through epoxy-filled recesses in a simplified manner, for example, by a sawing process.

According to at least one embodiment or design, the openings are created in the base material of a part of the recesses. The base material can be provided by a molding process, for example, via the vacuum injection molding, with a shape suitable for the openings, which is suitable, for example, for a filling opening or anchoring structure.

The radiation-emitting semiconductor component is suitable, for example, for general illumination and illumination in vehicles.

### BRIEF DESCRIPTION OF THE DRAWINGS

Further advantages, advantageous embodiments, and refinements result from the exemplary embodiments described hereinafter in conjunction with the figures.

FIG. 1A shows a schematic cross-sectional view and FIG. 1B shows a schematic top view of a radiation-emitting semiconductor component according to a first exemplary embodiment;

FIG. 2A shows a schematic cross-sectional view and FIG. 2B shows a schematic top view of a radiation-emitting semiconductor component according to a second exemplary embodiment;

FIGS. 3 to 5 show schematic top views of radiation-emitting semiconductor components according to further exemplary embodiments;

FIG. 6 shows a schematic cross-sectional view of a radiation-emitting semiconductor component according to a further exemplary embodiment; and

FIGS. 7A to 7E, 8 to 16, 17A and 17B, and 18 show schematic cross-sectional and top views of method steps of a method or possible variants for producing radiation-emitting semiconductor components.

### DETAILED DESCRIPTION OF ILLUSTRATIVE EMBODIMENTS

In the exemplary embodiments and figures, identical, similar, or identically-acting elements can each be provided with the same reference signs. The elements shown and their size relationships to one another are not necessarily to scale; rather, individual elements can be shown exaggeratedly large for better illustration capability and/or for better comprehension.

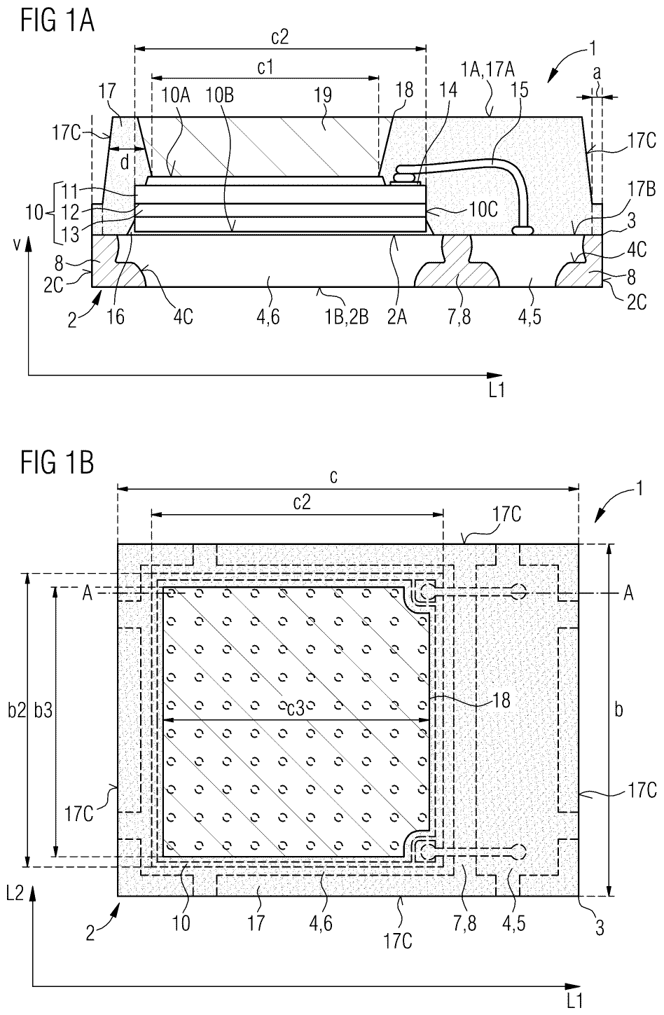

A first exemplary embodiment of a radiation-emitting semiconductor component 1 will be explained in more detail on the basis of FIGS. 1A and 1B. FIG. 1A shows a schematic view of a cross section of the radiation-emitting semiconductor component 1 along line A-A shown in FIG. 1B.

The radiation-emitting semiconductor component 1 comprises a carrier 2 and a semiconductor chip 10, which is arranged on a first main surface 2A of the carrier 2.

The carrier 2 comprises a carrier substrate 4 having a first connection element 5 of a first polarity and a second connection element 6 of a second polarity, wherein the first and second connection elements 5, 6 are spaced apart from one another by an electrically insulating intermediate space 7. For example, the carrier substrate 4 is a metallic substrate, such as a lead frame, wherein the connection elements 5, 6 are parts of the lead frame. However, it is also possible that the carrier 2 comprises a printed circuit board (PCB) or a ceramic substrate. The first and second connection elements 5, 6 form electrodes of the radiation-emitting semiconductor component 1, which are provided for the electrical contacting of the radiation-emitting semiconductor component 1 from the outside on its rear side 1B, which can be formed by a second main surface 2B of the carrier 2.

The carrier 2 additionally comprises a base material 8, which is arranged in the intermediate space 7 and covers the carrier substrate 4 on lateral surfaces 4C, which laterally delimit the carrier substrate 4. The base material 8 can be an electrically insulating material, for example, a plastic material such as an epoxy, which is distinguished at the same time by a higher hardness than silicone, for example.

The semiconductor chip 10 can be a surface emitter, which comprises an electrical contact 14 on its upper side facing away from the carrier 2 and an electrical contact (not shown) on its lower side facing toward the carrier 2. However, it is also possible that a volume emitter or flipchip is used as the semiconductor chip 10. Furthermore, it is possible that the semiconductor component 1 comprises further semiconductor chips, for example, an ESD (electrostatic discharge) protective diode and/or light-emitting diodes of other colors. Accordingly, the semiconductor component 1 can comprise further connection elements for electrically contacting the semiconductor chips.

The semiconductor chip 10 is mechanically and also electrically connected to the second connection element 6 on a base surface 10B facing toward the carrier 2 by a connecting means 16, for example, a solder layer or adhesive layer. Furthermore, the semiconductor chip 10 is connected to the first connection element 5 on the upper side or on a radiation emission face 10A, which is located on a side facing away from the carrier 2, via a connecting means 15 arranged at the contact 14, for example, a bond wire.

The semiconductor chip 10 comprises a first semiconductor area 11 of a first conductivity, such as a p-conductivity, and a second semiconductor area 13 of a second conductivity, such as an n-conductivity, and an active zone 12 arranged between the first and second semiconductor area 11, 13, which is intended for generating electromagnetic radiation, for example, having a wavelength in the ultraviolet, visible, or infrared spectral range. The first semiconductor area 11 is located on a side of the active zone 12 facing away from the carrier 2 and can be electrically contacted via the upper-side contact 14, while the second semiconductor area 13 is arranged on a side of the active zone 12 facing toward the carrier 2 and can be electrically contacted via the lower-side contact. However, it is also possible that the p-conductive semiconductor area is arranged on the carrier side and the n-conductive area is arranged on a side facing away from the carrier 2.

As already mentioned above, the first and second semiconductor area 11, 13 and the active zone 12 can each be formed from one or more semiconductor layers, wherein the semiconductor layers can be layers deposited epitaxially on a growth substrate, and the growth substrate can remain in the semiconductor chip 10 or can be at least partially detached after the growth of the semiconductor layers. Materials based on arsenide, phosphide, or nitride compound semiconductors come into consideration, for example, for the semiconductor areas 11, 12, 13 or semiconductor layers of the semiconductor chip 10, as explained in more detail above.

Furthermore, the radiation-emitting semiconductor component 1 comprises a housing 17. The housing 17 is molded onto the carrier 2 and the semiconductor chip 10. The housing 17 can thus be mechanically connected to the carrier 2 and the semiconductor chip 10 without additional connecting means such as adhesive and can cling to the carrier 2 or the semiconductor chip 10 in areas in which it is molded on.

The carrier 2 comprises multiple lateral surfaces 2C, which each connect the first main surface 2A to the second main surface 2B opposite to the first main surface 2A. The lateral surfaces 2C of the carrier 2 and the second main surface 2B are uncovered by the housing 17. The uncovered surfaces 2C, 2B of the carrier 2 enable good heat dissipation.

Furthermore, the semiconductor chip 10 comprises multiple lateral surfaces 10C, which each connect the radiation emission face 10A to the base surface 10B. The lateral surfaces 10C are covered by the housing 17, wherein the housing 17 extends from the first main surface 2A of the carrier 2 via the lateral surfaces 10C of the semiconductor chip 10 beyond the radiation emission face 10A of the semiconductor chip 10. In other words, the housing 17 can protrude beyond the semiconductor chip 10 in a vertical direction V, which extends perpendicularly to a first and a second lateral direction L1, L2 (cf. FIGS. 1A and 1B). The first and second lateral direction L1, L2 span a plane to which the first main surface 2A is arranged parallel. The radiation emission face 10A can be partially covered by the housing 17.

The housing 17 is laterally delimited by multiple housing walls 17C, wherein the housing walls 17C each connect a housing upper side 17A facing away from the carrier 2 to a housing lower side 17B facing toward the carrier 2 and in some areas extend transversely to the housing upper side 17A and the housing lower side 17B.

The housing walls 17c are each laterally offset inward in the direction toward a center point of the housing 17 in sections in relation to an edge 3 of the carrier 2 delimiting the first main surface 2A. In other words, the housing walls 17C each have a lateral distance a to the edge 3 of the carrier 2 in some areas in a vertical projection on the first main surface 2A of the carrier 2. The edge 3 of the carrier 2 protrudes laterally beyond the housing walls 17c in a vertical projection on the first main surface 2A of the carrier 2. The lateral distance a is defined parallel to the plane spanned by the first and second lateral direction L1, L2. The lateral distance a is greater than zero and is, for example, at most 20 μm. The lateral distance a can increase continuously in the vertical direction V, so that the housing walls 17C extend at an angle greater than 0° and less than 90° to the first main surface 2A of the carrier 2. In an area arranged at the first main surface 2A, the housing walls 17C can be arranged without a distance or with distance a=0 to the carrier edge 3, so that the housing 17 ends flush with the carrier 2.

The lateral distance a results from separating trenches 33 (cf. FIG. 16), which are provided during the production in the composite between adjacent housings 17, as will be explained in more detail hereinafter in conjunction with the method.

The housing 17 comprises a depression 18, which extends from the housing upper side 17A to the radiation emission face 10A of the semiconductor chip 10 and ends at the radiation emission face 10A, wherein the depression 18 tapers in the direction of the semiconductor chip 10. The depression 18 is designed so that it does not protrude laterally beyond the semiconductor chip 10 on a side facing toward it. In other words, the depression 18 can have a first lateral dimension (not shown) and second lateral dimension c1 on a side facing toward the semiconductor chip 10, which are at most as large as the first and second lateral dimensions c2, b2 (cf. FIG. 1B) of the radiation emission face 10A. The first lateral dimensions c1, c2 are defined parallel to the first lateral direction L1 and the second lateral dimensions are defined parallel to the second lateral direction L2.

The housing walls 17c are each laterally offset in some sections in the direction toward the depression 18 in relation to the edge 3 of the carrier 2 delimiting the first main surface 2A.

The housing 17 is preferably a housing molded on using vacuum injection molding (VIM), as will be explained in more detail hereinafter in conjunction with the method. The housing 17 created using vacuum injection molding can comprise sharp edges having relatively small radius of curvature, for example, less than 10 μm, for example, in each case at the transition from the housing upper side 17A to the housing walls 17C and at the transition from the housing upper side 17A to the depression 18.

The housing 17 is used as a reflector and is formed from a housing material containing a reflective material. The reflective material can comprise, for example, particles made of TiO2 and/or ZrO2. A mean particle size is advantageously at most 1 μm, wherein the mean particle size is to be understood as the median value. Particles of this size can be processed well using vacuum injection molding (VIM). Furthermore, the housing material can contain a plastic material. Silicone comes into consideration as a plastic material, for example. The reflective material or the particles can be homogeneously distributed in the plastic material. The housing material can differ from the base material 8.

The housing 17 is intended to reflect radiation emitted at the lateral surfaces 10C of the semiconductor chip 10 with a reflectivity of at least 50%. A part of the radiation can be deflected in the direction of the depression 18 or a front side 1A of the semiconductor component 1, which is partially formed by the housing upper side 17A.

A filler compound 19, which completely fills the depression 18, is arranged in the depression 18. The filler compound 19 does not protrude beyond the housing upper side 17A. The filler compound 19 can contain a converter material intended for wavelength conversion of the primary radiation generated by the semiconductor chip 10, so that at least a part of the radiation emitted by the semiconductor chip 10 experiences a change of the wavelength, for example, a shift toward longer wavelengths, due to the filler compound 19. Due to a superposition of the primary radiation with a secondary radiation coming from the filler compound 19, the radiation-emitting semiconductor component 1 can emit white light, for example, by a combination of blue primary radiation and yellow secondary radiation, but also colored light or invisible radiation. For example, the front side 1A is the radiation exit side of the semiconductor component 1.

The housing 17 created using vacuum injection molding (VIM) advantageously enables small dimensions in the housing 17 itself and also in the radiation-emitting semiconductor component 1. For example, the housing 17 can largely be formed having a mean thickness d of approximately 0.1 mm in areas in which it borders the depression 18. Furthermore, a luminous surface, which can correspond in its dimensions to a first lateral dimension c3 and a second lateral dimension b3 of the depression 18 at the front side 1A (cf. FIG. 1B), can comprise a size of c3˜1.4 mm and b3˜1.4 mm. A small luminous surface can be depicted better by optical systems. The luminous surface can be smaller than the radiation emission face 10A, so that the luminance is increased. Furthermore, the semiconductor component 1 can have a first lateral dimension c=2 mm and a second lateral dimension b=1.6 mm, wherein deviations of ±10% can occur due to production.

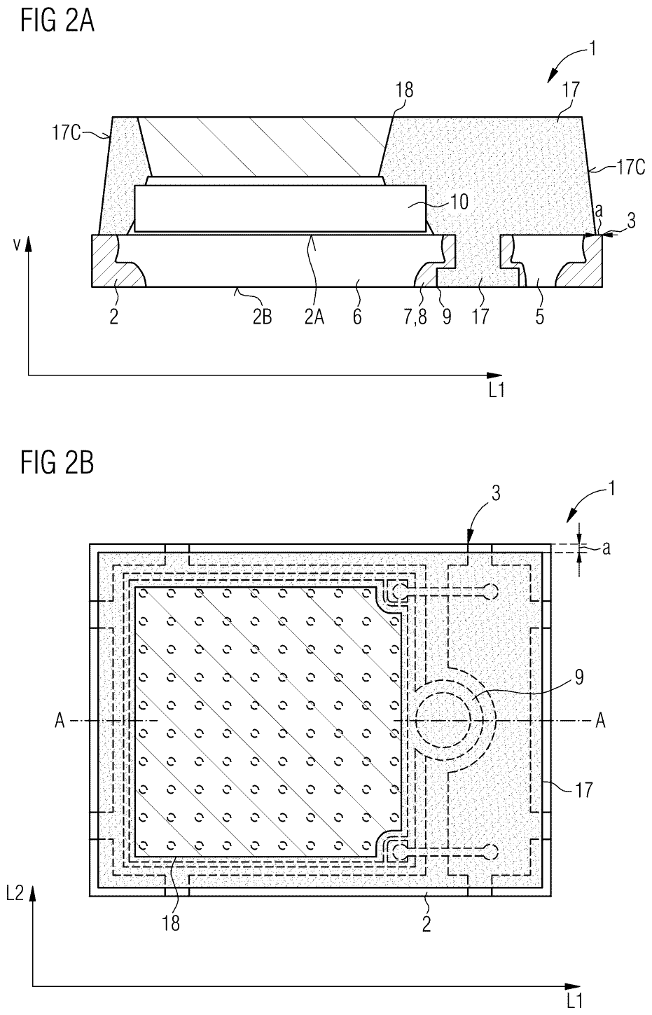

A second exemplary embodiment of a radiation-emitting semiconductor component 1 will be explained in more detail on the basis of FIGS. 2A and 2B. FIG. 2A shows a schematic view of a cross section of the radiation-emitting semiconductor component 1 along line A-A shown in FIG. 2B.

The radiation-emitting semiconductor component 1 comprises a carrier 2, a semiconductor chip 10 arranged on the carrier 2, and a housing 17 molded onto the carrier 2 and the semiconductor chip 10. All housing walls 17C are already offset laterally inward in relation to the edge 3 of the carrier 2 at the first main surface 2A of the carrier 2 and comprise a lateral distance a to the carrier edge 3 which is greater than zero. The lateral distance a can continuously increase in the vertical direction V, so that the housing walls 17C extend at an angle greater than 0° and less than 90° in relation to the first main surface 2A of the carrier 2. Due to the lateral spacing apart of all housing walls 17C, the carrier 2 has an edge area uncovered by housing material along the carrier edge 3 at the first main surface 2A, which can be cut through more easily during the isolation from a composite because of the absence of housing material.

The carrier 2 comprises an opening 9, into which the housing 17 extends, so that the opening 9 is filled with housing material. For example, the opening 9 is used during the production of the housing 17 as a filling opening, through which a molding compound is introduced into a cavity. It is possible that the carrier 2 comprises multiple openings 9, into which the housing 17 extends (not shown).

The opening 9 extends from the first main surface 2A of the carrier 2 through the carrier 2 up to the second main surface 2B of the carrier 2. The opening 9 is larger at the second main surface 2B than at the first main surface 2A and comprises a polygonal multistep cross section parallel to a plane spanned by the vertical direction V and the first lateral direction L1 (cf. FIG. 2A). Due to the opening 9 widening toward the second main surface 2B, the housing material arranged therein and therefore the housing 17 as a whole can be anchored particularly well in the carrier 2. Furthermore, the opening 9 can have a circular cross section parallel to a plane spanned by the first lateral direction L1 and the second lateral direction L2 (cf. FIG. 2B).

The opening 9 is arranged in a space-saving manner in the intermediate space 7 present in any case between the first and second connection element 5, 6. The housing material arranged in the opening 9 is embedded in the base material 8 arranged in the intermediate space 7.

The radiation-emitting semiconductor component 1 described in conjunction with FIGS. 2A and 2B can additionally comprise all features and advantages mentioned in conjunction with the further exemplary embodiments.

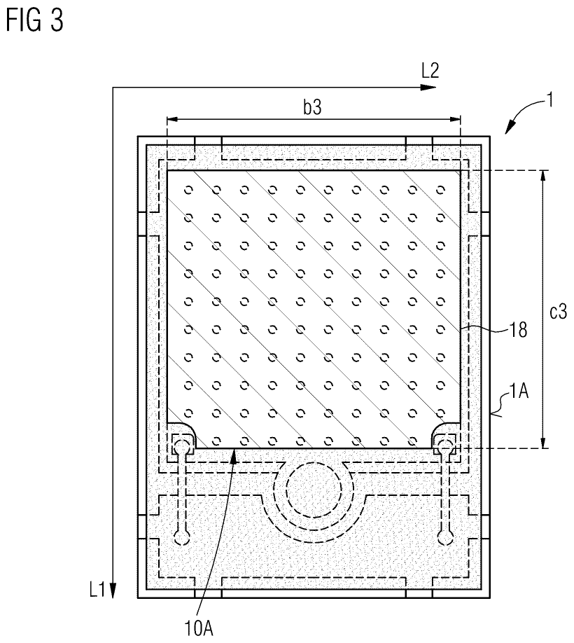

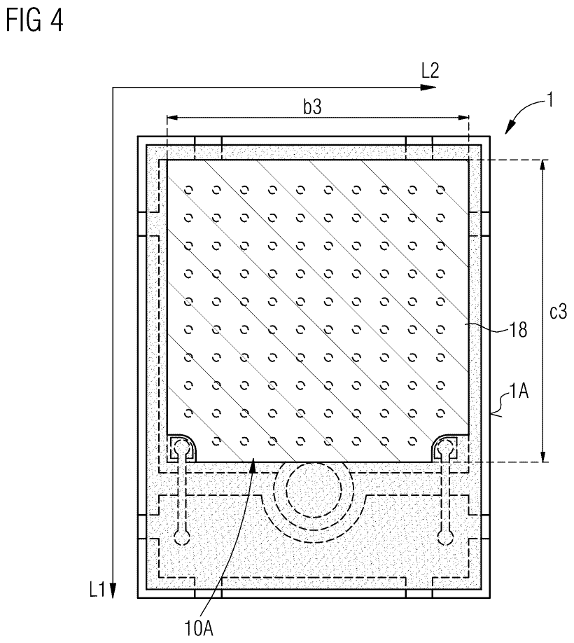

Further exemplary embodiments of a radiation-emitting semiconductor component 1 will be explained in more detail on the basis of FIGS. 3 and 4.

As shown in FIG. 3, the luminous surface, which can correspond in its dimensions to the first lateral dimension c3 and the second lateral dimension b3 of the depression 18 on the front side 1A, can be of similar size to the radiation emission face 10A of the semiconductor chip 10. In comparison to the preceding exemplary embodiments, in which the luminous surface is smaller than the radiation emission face 10A, the luminous flux can be increased in this case.

As shown in FIG. 4, the luminous surface, which can correspond in its dimensions to the first lateral dimension c3 and the second lateral dimension b3 of the depression 18 on the front side 1A, can also be larger than the radiation emission face 10A of the semiconductor chip 10, so that all customer requirements for the size of the luminous surface can in principle be taken into consideration.

The radiation-emitting semiconductor components 1 described in conjunction with FIGS. 3 and 4 can additionally comprise all features and advantages mentioned in conjunction with the further exemplary embodiments.

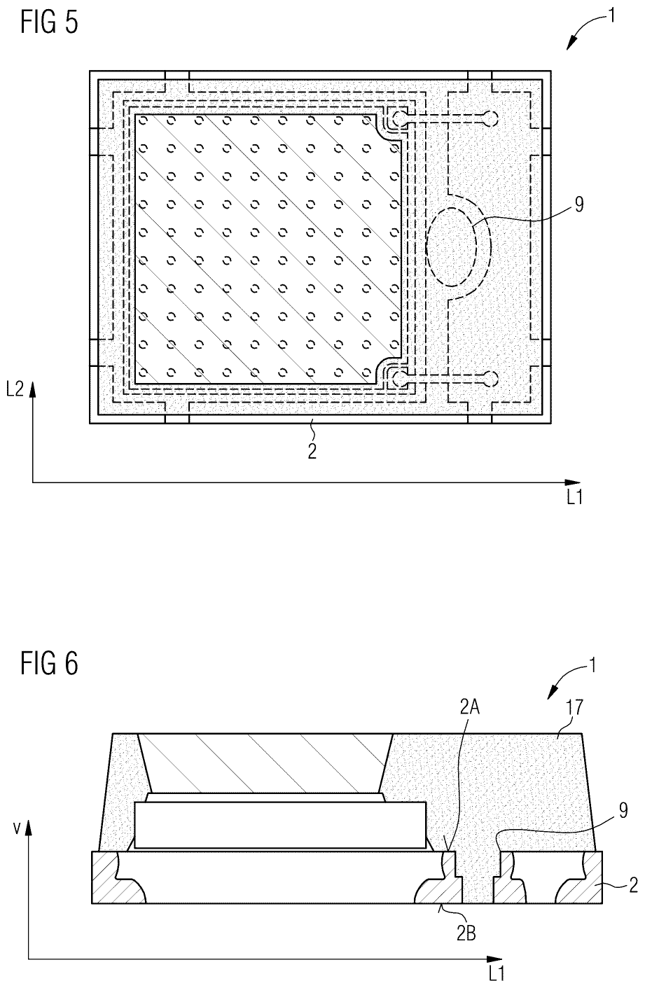

A further exemplary embodiment of a radiation-emitting semiconductor component 1 will be explained in more detail on the basis of FIG. 5. The radiation-emitting semiconductor component 1 comprises a carrier 2 having an opening 9, which comprises an elliptical cross section parallel to a plane spanned by the first lateral direction L1 and the second lateral direction L2. Furthermore, the opening 9 can have a trapezoidal or multistep cross section parallel to a plane spanned by the vertical direction V (cf. FIG. 6 in this regard) and the first lateral direction L1. The radiation-emitting semiconductor component 1 can additionally comprise all features and advantages mentioned in conjunction with the further exemplary embodiments.

A further exemplary embodiment of a radiation-emitting semiconductor component 1 will be explained in more detail on the basis of FIG. 6. The radiation-emitting semiconductor component 1 comprises a carrier 2 having an opening 9, which is smaller at the second main surface 2B than at the first main surface 2A and has a multistep cross section parallel to a plane spanned by the vertical direction V and the first lateral direction L1. The opening 9 is particularly suitable during the production of the housing 17 as a filling opening, through which a molding compound is introduced into a cavity. The radiation-emitting semiconductor component 1 can additionally comprise all features and advantages mentioned in conjunction with the further exemplary embodiments.

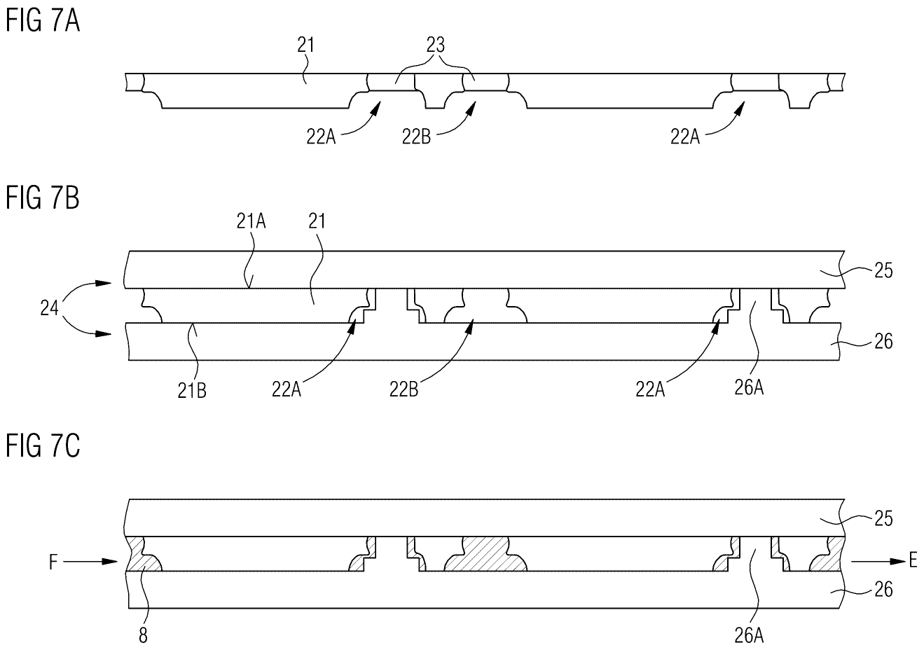

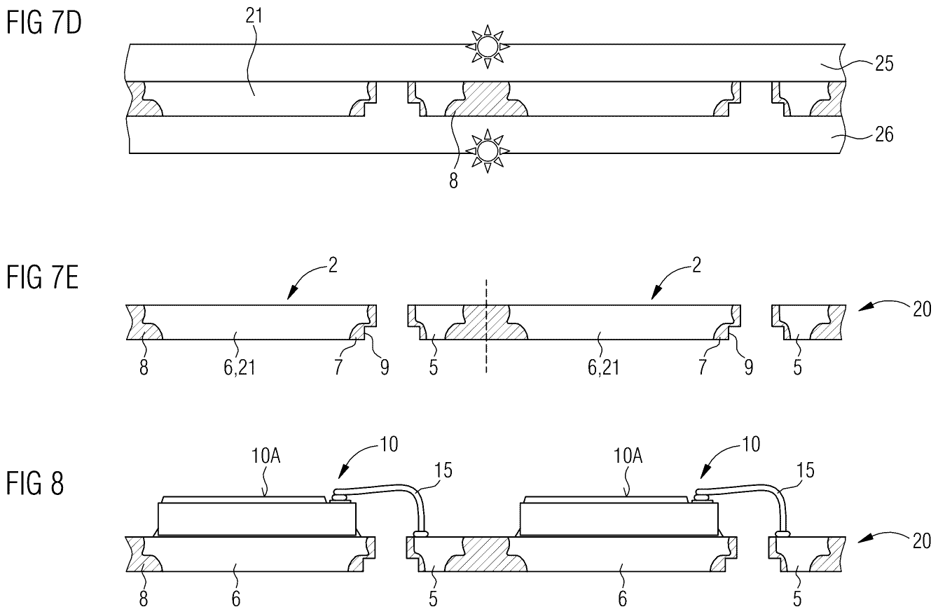

A method for producing radiation-emitting semiconductor components 1, such as those explained in more detail in conjunction with the preceding figures, will be described on the basis of FIGS. 7 to 18. Furthermore, possible variants of the method will be described.

The method comprises providing a carrier composite 20, which comprises a carrier body 21 and a base material 8 (cf. FIG. 7E). Providing the carrier composite 20 can comprise a step of providing the carrier body 21, which comprises recesses 22A, 22B (cf. FIG. 7A). Due to the recesses 22A, 22B, the carrier body 21 can comprise areas separated from one another, which can be held together by a support structure 23. For example, the carrier body 21 can be a lead frame composite. However, it is also possible that the carrier body 21 is a composite made of printed circuit boards or a composite made of ceramic substrates. The recesses 22A can be intended for the purpose of forming intermediate spaces 7 between connection elements 5, 6 of different polarity (cf. FIG. 7E) in carriers 2 which are isolated from the carrier composite 20. The recesses 22B can be intended for the purpose of separating by way of intermediate spaces the connection elements 5, 6 of various carriers 2 to be isolated from one another.

Furthermore, providing the carrier composite 20 can comprise a step of introducing the base material 8 into the recesses 22A, 22B (cf. FIG. 7C). For example, the base material 8 is introduced into the recesses 22A, 22B using vacuum injection molding, wherein a molding tool 24 having a first tool half 25 and a second tool half 26 is provided, between which the carrier body 21 is arranged, so that a first surface 21A of the carrier body 21 is covered by the first tool half 25 and a second surface 21B of the carrier body 21 is covered by the second tool half 26 (cf. FIG. 7B). A vacuum E is generated in the molding tool 24 and the base material 8 is injected into the recesses 22A, 22B at a filling pressure F, for example, between 0.1 and 0.5 bar. The injection can take place at room temperature. The base material 8 can differ from the molding compound 32, from which the housings are produced. The base material 8 can be a plastic material, for example, an epoxy. The epoxy is hard in comparison to silicone, so that a later isolation of the carriers 2 can take place through the epoxy-filled recesses 22B in a simplified manner, for example, by a sawing process.

The first tool half 25 can be formed flat. The second tool half 26 can also be formed flat or can comprise protruding parts 26A (cf. FIG. 7B), if, for example, openings 9 are to be created in the carriers 2 to be isolated (cf. FIG. 7E). The protruding parts 26A can each engage in one recess 22A, so that the recesses 22A are only partially filled by the base material 8, while the recesses 22B are completely filled (cf. FIG. 7C). For example, the tool halves 25, 26 can be produced with the aid of additive manufacturing, so that more complex geometries as in the protruding parts 26A, for example, which provide the openings 9 with their shape, which is suitable, for example, for a filling opening or anchoring structure, can also be implemented. For example, the tool halves 25, 26 can comprise polydimethylsiloxane (PDMS) or can consist thereof.

As indicated in FIG. 7D by star symbols, the base material 8 can be cured by the effect of light, for example, UV light. In addition, the base material 8 can also be thermally cured after the demolding (cf. FIG. 7E).

After the provision of the carrier composite 20, radiation-emitting semiconductor chips 10 are applied thereon, wherein the radiation-emitting semiconductor chips 10 each comprise a radiation emission face 10A, which is arranged on a side facing away from the carrier composite 20 (cf. FIG. 8). For example, in each case a semiconductor chip 10 is mounted on a second connection element 6 and connected via a connecting means 15 to an adjacent first connection element 5.

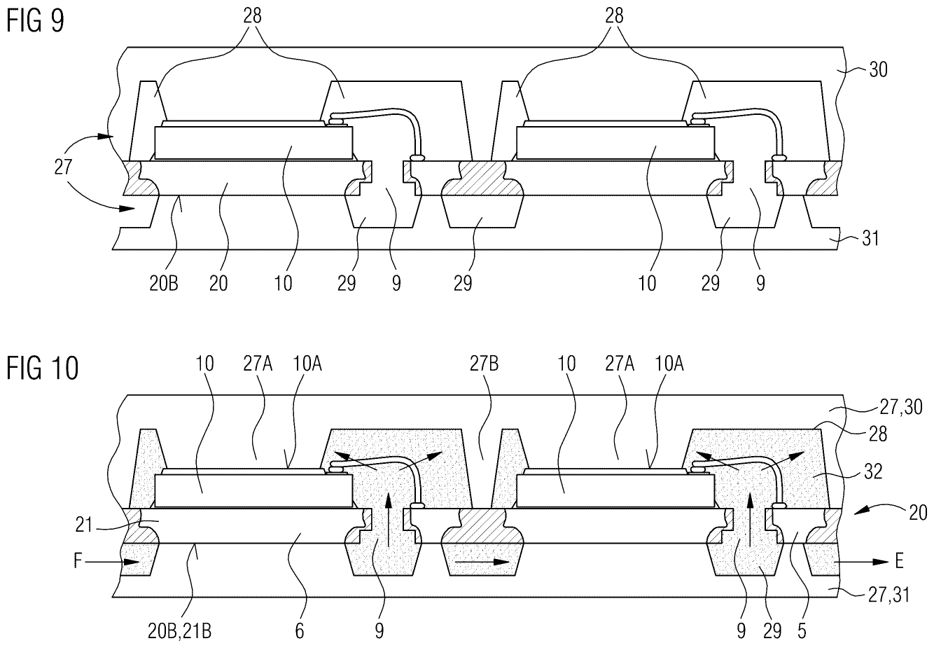

To produce housings 17 (cf. FIGS. 1 to 6), the method furthermore comprises providing a further molding tool 27 having cavities 28 and arranging the carrier composite 20 having the semiconductor chips 10 applied thereon relative to the molding tool 27 such that one semiconductor chip 10 is arranged in each cavity 28 (cf. FIG. 9). Furthermore, the molding tool 27, if the carrier composite 20 comprises openings 9, can comprise channels 29, which, after the introduction of the carrier composite 20 into the molding tool 27, are located on a rear side 20B of the carrier composite 20 facing away from the semiconductor chips 10 and are open toward the openings 9. For example, the molding tool 27 can comprise a first tool half 30 having the cavities 28 and a second tool half 31 having the channels 29, wherein the carrier composite 20 having the semiconductor chips 10 arranged thereon is laid between the two tool halves 30, 31.

The molding tool 27 or its parts, such as the first tool half 30 and the second tool half 31, can be produced via additive manufacturing. It is thus possible to implement cavities 28 and channels 29 having more complex geometry. For example, the tool halves 30, 31 can contain polydimethylsiloxane (PDMS) or can consist thereof. Surfaces of the tool halves 30, 31 formed by PDMS are distinguished by a high surface quality.

The method furthermore comprises filling the cavities 28 with a molding compound 32 (cf. FIG. 10) to produce housings 17 (cf. FIGS. 1 to 6), wherein the semiconductor chips 10 are each covered by a part 27A of the molding tool 27 to produce depressions 18 in the housings 17 at the radiation emission faces 10A, and wherein to produce a separating trench 33 between each two adjacent housings 17, each two adjacent cavities 28 are spaced apart from one another by a further part 27B of the molding tool 27. The filling of the cavities 28, if the carrier composite 20 comprises openings 9, can take place via the channels 29 from the rear side 20B, wherein the molding compound 32 is introduced into the channels 29 and passes from these through the openings 9 into the cavities 28 (cf. arrows). The openings 9 can also be filled with molding compound, so that the housings 17 each protrude into the associated openings 9 and can thus be anchored in the carriers 2 (cf. FIG. 16).

The molding compound 32 comprises the same material components as the housing material and can accordingly contain a plastic material, such as silicone, and a reflective material, such as particles made of TiO2 and/or ZrO2.

The housings 17 are preferably produced using vacuum injection molding (VIM). The molding compound 32 is injected for this purpose into the cavities 28, in which a vacuum E is generated. A filling pressure F prevailing during the injection can be between 0.1 and 0.5 bar. It is possible via the vacuum injection molding to implement small housing sizes with high precision and sharp edges, as already described in conjunction with FIGS. 1 to 6. A further advantage is that the formation of air bubbles, which generally make the housings 17 brittle, can be prevented, so that the housings 17 and likewise the semiconductor components 1 are comparatively stable.

During the filling of the cavities 28 with the molding compound 32, the second surface 21B of the carrier body 21 can be covered in areas of the connection elements 5, 6 by parts of the molding tool 27 or the second tool half 31 and therefore can be protected from the molding compound 32, so that the connection elements 5, 6 are not covered by an electrically insulating film.

As can be seen from FIG. 11, the second tool half 31, in order to protect the connection elements 5, 6 from the molding compound 32 and therefore from an electrically insulating film, can be formed in two parts and can comprise a base plate 31A and an intermediate plate 31B, wherein the intermediate plate 31B is arranged between the carrier composite 20 and the base plate 31A and covers the rear side 20B of the carrier composite 20, with the exception of the openings 9, for protection. The channels 29 extend here between the base plate 31A and the intermediate plate 31B through the intermediate plate 31B to the openings 9. The base plate 31A and the intermediate plate 31B can each be produced from PDMS via additive manufacturing with the above-mentioned advantages.

The method can furthermore comprise a step of curing of the molding compound 32 arranged in the cavities 28. This can be carried out with the aid of UV light, as indicated by a star symbol.

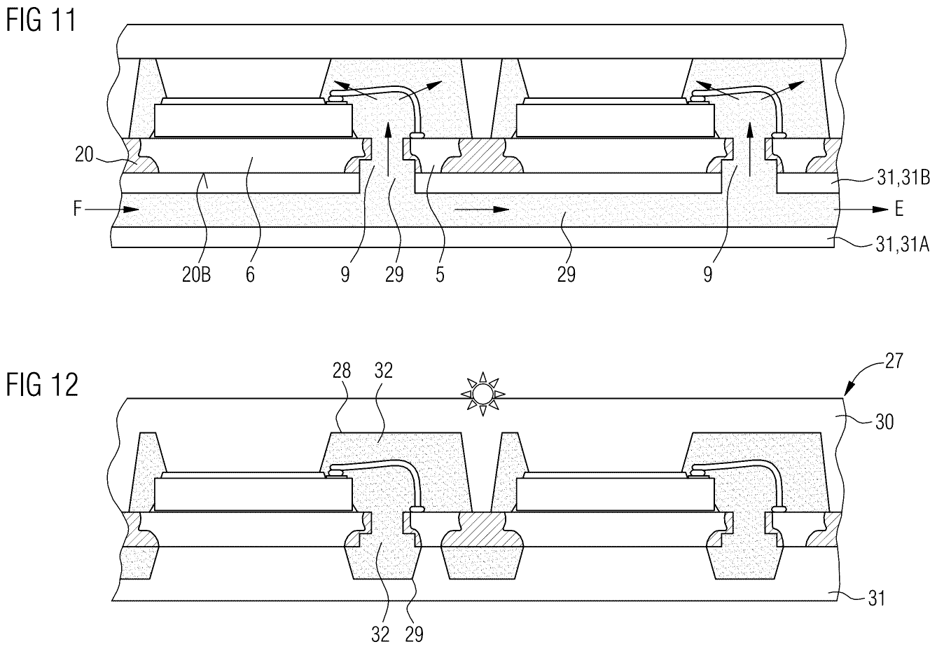

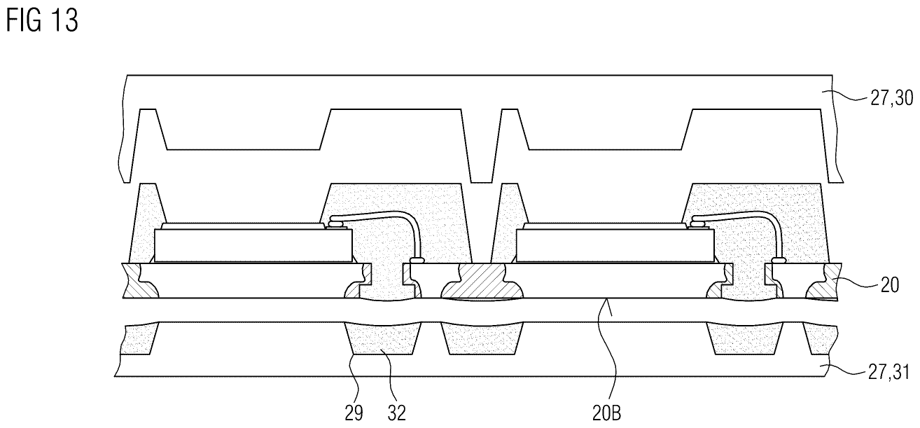

As shown in FIG. 12, the curing can be carried out on one side from an upper side of the molding tool 27, i.e. from the side of the first tool half 30. In this case, uncured molding compound 32 can remain in the channels 29 upon the removal of the molding tool 27, so that in this way undesired residues of the molding compound 32 on the rear side 20B of the carrier composite 20 can be removed (cf. FIG. 13).

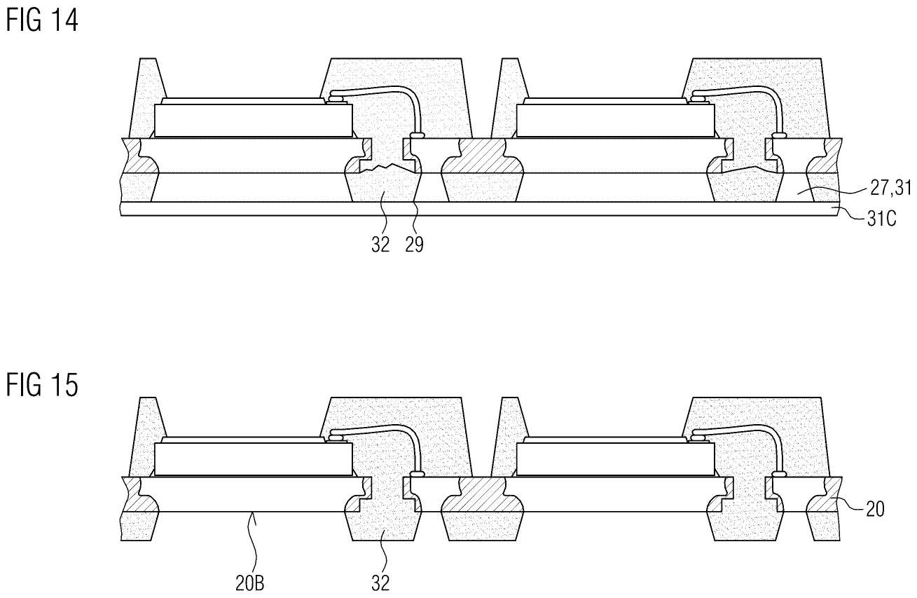

Alternatively, the curing can take place on both sides from the upper side and a lower side of the molding tool 27, i.e. from the side of the first tool half 30 and the second tool half 31. In this case, the molding compound 32 in the channels 29 is cured. The second tool half 31 comprises an adhesive film 31C, which adheres to the cured molding compound 32, so that the cured molding compound 32 is also removed upon the removal of the second tool half 31 (cf. FIG. 14).

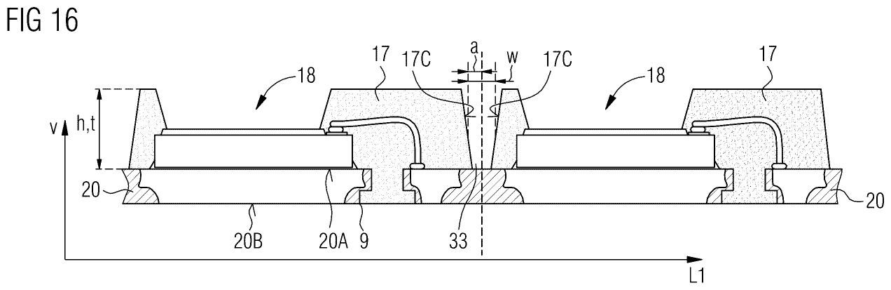

Alternatively, the curing can take place on both sides from the upper side and the lower side of the molding tool 27, i.e. from the side of the first tool half 30 and the second tool half 31, without adhesive film, so that, as shown in FIG. 15, residues of the molding compound 32 remain on the rear side 20B of the carrier composite 20 upon removal of the molding tool 27, which are subsequently removed, so that the carrier composite 20 no longer comprises residues on the rear side 20B (cf. FIG. 16).

As shown in FIG. 16, after the removal of the molding tool 27, multiple housings 17 are arranged on a front side 20A of the carrier composite 20 opposite to the rear side 20B, which are each molded onto a semiconductor chip 10 and the carrier composite 20 and comprise a depression 18. A separating trench 33 is located between each two adjacent housings 17, which is formed wide enough that after the isolation a housing wall 17C of a housing 17 adjoining it is offset laterally inward at least in some sections in relation to an edge 3 of the carrier 2 delimiting the first main surface 2A, on which the housing 17 is molded (cf. FIGS. 1 to 6).

The separating trench 33 has a width w, which corresponds to twice the lateral distance a of the housing wall 17C to the edge 3 of the carrier 2 (cf. FIGS. 1 to 6). For example, the width w of the separating trench 33 can decrease with increasing depth, i.e. opposite to the vertical direction V. The separating trench 33 can thus taper in the direction of the carrier composite 20. Accordingly, the housing wall 17C in the finished semiconductor component 1 can extend obliquely, i.e. neither perpendicular nor parallel, to the first main surface 2A of the carrier 2. Furthermore, the separating trench 33 can have a depth t which corresponds to at least 50% of a height of the housing wall, wherein the depth indicates a dimension along the negative vertical direction V and the height indicates a dimension along the negative vertical direction V.

The width w or depth t of the separating trench 33 is in particular selected so that during the isolation, no or only little housing material from which the housings 17 are each formed has to be cut through. In particular, the separating trench 33 is free of silicone. The isolation can thus be carried out without preceding steps for removing the silicone in a one-step process, for example, via sawing.

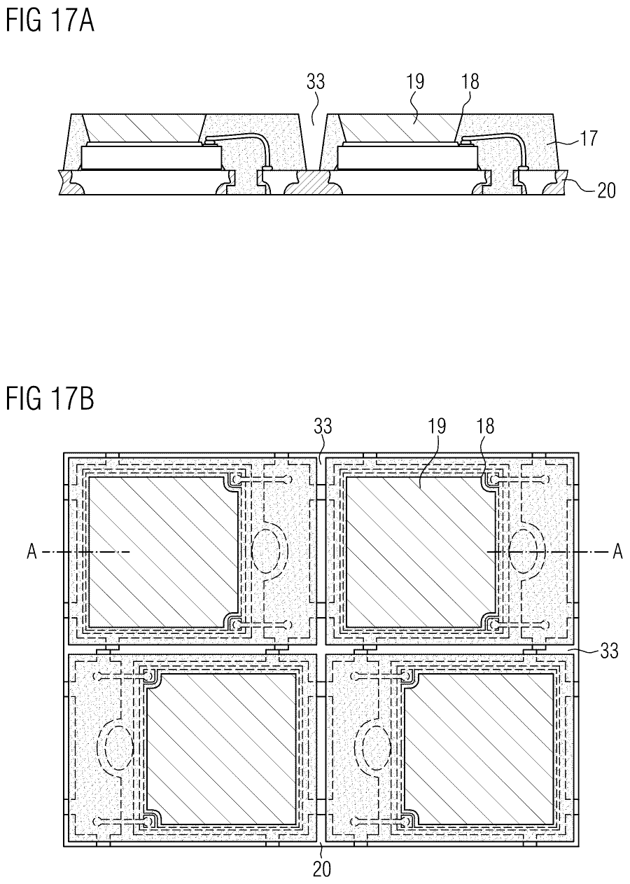

As shown in FIG. 17B in a schematic top view and in FIG. 17A in a schematic view of a cross section along line A-A shown in FIG. 17B, the method can comprise a step of introducing a filler compound 19 into the depressions 18. For example, the filler compound 19 can be introduced into the depressions 18 using a dispenser. As already mentioned above, the filler compound 19 can contain a converter material. The filler compound 19 can additionally comprise the above-described structural properties and material properties.

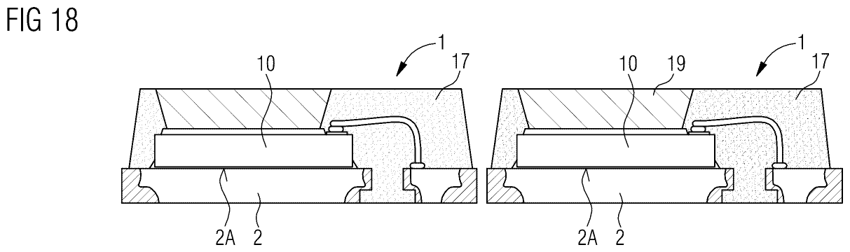

Furthermore, the method comprises a step of dividing the carrier composite 20 having the semiconductor chips 10 applied thereon and the molded-on housings 17 through the respective separating trenches 33, wherein carriers 2 of the radiation-emitting semiconductor components 1 are isolated from the carrier composite 20, which each comprise a first main surface 2A, on which at least one semiconductor chip 10 and a housing 17 is arranged, so that a plurality of radiation-emitting semiconductor components 1 result (cf. FIG. 18). The isolation or division, which can be carried out with the aid of sawing, is essentially restricted to the isolation or division of the carrier composite 20, since the housings 17 are spaced apart from the respective separating trench 33 and therefore only little or no housing material has to be cut through. Prior processes for eliminating housing material are advantageously eliminated due to the formation of the separating trenches 33. Furthermore, the base material 8 of the carrier composite 20, which can be harder in comparison to the housing material, is easier to cut through, so that the method is made efficient as a whole.

The invention is not restricted by the description on the basis of the exemplary embodiments. Rather, the invention comprises each novel feature and each combination of features, which in particular includes each combination of features in the claims, even if this feature or this combination is not itself explicitly indicated in the claims or exemplary embodiments.

1.-20. (canceled)

21. A radiation-emitting semiconductor component comprising:
a carrier having a first main surface and at least one lateral surface extending transversely to the first main surface;
at least one semiconductor chip arranged on the first main surface of the carrier and configured to emit radiation at a radiation emission face; and
a housing molded onto the carrier and the at least one semiconductor chip,
wherein the at least one lateral surface of the carrier is uncovered by the housing,
wherein the housing comprises a depression arranged on the radiation emission face of the at least one semiconductor chip,
wherein the housing is laterally delimited by at least one housing wall, and
wherein the at least one housing wall is laterally offset in a direction toward the depression with respect to an edge of the carrier delimiting the first main surface.

22. The radiation-emitting semiconductor component according to claim 21, wherein the housing is a housing molded by using vacuum injection molding.

23. The radiation-emitting semiconductor component according to claim 21, wherein the housing consists of a housing material containing a reflective material.

24. The radiation-emitting semiconductor component according to claim 23, wherein the reflective material comprises particles made of TiO2 and/or ZrO2.

25. The radiation-emitting semiconductor component according to claim 23, wherein the housing material contains a plastic material.

26. The radiation-emitting semiconductor component according to claim 21, further comprising a filler compound arranged in the depression.

27. The radiation-emitting semiconductor component according to claim 26, wherein the filler compound contains a converter material configured to convert a wavelength of the radiation.

28. The radiation-emitting semiconductor component according to claim 21, wherein the carrier comprises an opening into which the housing extends.

29. The radiation-emitting semiconductor component according to claim 28, wherein the opening extends from the first main surface of the carrier through the carrier to a second main surface of the carrier opposite to the first main surface.

30. The radiation-emitting semiconductor component according to claim 29, wherein the opening is larger at the second main surface than at the first main surface.

31. The radiation-emitting semiconductor component according to claim 28, wherein the carrier comprises a first connection element of a first polarity and a second connection element of a second polarity, the second connection element being spaced apart by an intermediate space from the first connection element, and wherein the opening is arranged in the intermediate space.

32. The radiation-emitting semiconductor component according to claim 21, wherein the depression does not protrude laterally beyond the at least one semiconductor chip on a side facing toward it.

33. The radiation-emitting semiconductor component according to claim 21, wherein the depression extends from a housing upper side, which is arranged on a side of the housing facing away from the carrier, to the radiation emission face of the at least one semiconductor chip and ends at the radiation emission face.

34. A method for producing radiation-emitting semiconductor components, the method comprising:
providing a carrier composite;
applying radiation-emitting semiconductor chips to the carrier composite, wherein each of the radiation-emitting semiconductor chips comprises a radiation emission face;
providing a molding tool having cavities;
arranging the carrier composite having the radiation-emitting semiconductor chips applied thereon and the molding tool relative to each other such that at least one radiation-emitting semiconductor chip is arranged in each cavity;
filling the cavities with a molding compound to produce housings, wherein each of the radiation-emitting semiconductor chips is covered by a part of the molding tool to form depressions in the housings at the radiation emission faces, and wherein each two adjacent cavities are spaced apart from one another by a further component of the molding tool to form a separating trench between each two adjacent housings; and
singulating the carrier composite having the radiation-emitting semiconductor chips applied thereon and the molded-on housings through the respective separating trenches,
wherein carriers of the radiation-emitting semiconductor components are formed from the carrier composite, each carrier comprising a first main surface on which at least one radiation-emitting semiconductor chip is arranged, and
wherein each of the separating trenches is formed wide enough such that an adjoining housing wall of a housing is laterally offset after singulation, in a direction toward a depression, with respect to an edge of the carrier delimiting the first main surface on which the housing is molded.

35. The method according to claim 34, wherein the housings are formed by vacuum injection molding.

36. The method according to claim 34, wherein parts of the molding tool, which delimit the cavities, are formed by additive manufacturing.

37. The method according to claim 34, further comprising introducing a filler compound into the depressions using a dispenser.

38. The method according to claim 34, wherein the carrier composite comprises openings, wherein at least one opening is assigned to each carrier to be isolated, and wherein the molding compound is introduced through the openings into the cavities.

39. The method according to claim 34, wherein providing the carrier composite comprises:
providing a carrier body having recesses, and
introducing a base material into the recesses,
wherein the base material is introduced by vacuum injection molding.

40. The method according to claim 38, wherein the openings are created in a base material of a part of recesses.
